(19) United States
(12) Patent Application Publication
(10) Pub. No.: US 2026/0171368 A1
(43) Pub. Date: Jun. 18, 2026

(54) BOND PROTECTION FOR AN ELECTROSTATIC CHUCK IN A PLASMA PROCESSING CHAMBER

(71) Applicant: Lam Research Corporation, Fremont, CA (US)

(72) Inventors: Kadthala R NARENDRNATH, San Jose, CA (US); Neha KONDEKAR, Portland, OR (US); Yixuan YU, Fremont, CA (US); Slobodan MITROVIC, Oakland, CA (US); Eric SAMULON, Oakland, CA (US); Moreshwar Narayan PURANDARE, San Jose, CA (US)

(21) Appl. No.: 19/103,199

(22) PCT Filed: Aug. 16, 2023
(86) PCT No.: PCT/US2023/030343

§ 371 Date: Feb. 11, 2025

Related U.S. Application Data
(60) Provisional application No. 63/399,148, filed on Aug. 18, 2022.

(51) Int. Cl. H01J 37/32; H01J 9/30

(52) U.S. Cl. CPC H01J 37/32495; H01J 9/30; H01J 37/32467; H01J 37/32715; H01J 2237/0213; H01J 2237/2007

(57) ABSTRACT

An electrostatic chuck system for use in a plasma processing chamber is provided. A conductive base plate is provided. A bond of a bonding material is bonded to a surface of the base plate on a first side of the bond. A ceramic plate is bonded to a second side of the bond. A protective strip surrounds the bond and extends between the conductive base plate and the ceramic plate, wherein the protective strip comprises at least one of an anodized strip, a ceramic tape strip, and a coated aluminum strip.

### CROSS-REFERENCE TO RELATED APPLICATION

This application claims the benefit of priority of U.S. Application No. 63/399,148, filed Aug. 18, 2022, which is incorporated herein by reference for all purposes.

### BACKGROUND

This disclosure relates to components in plasma processing chambers used in semiconductor processing. More specifically, the disclosure relates to electrostatic chucks used in plasma processing chambers.

In plasma processing chambers, electrostatic chucks are used to support substrates being processed. The electrostatic chucks may be subjected to different temperatures and various plasma processes. Some electrostatic chucks provide a ceramic plate bonded to a metal base plate. A bonding material bonds the ceramic plate to the metal base plate and is sufficiently flexible to accommodate different coefficients of thermal expansion for the ceramic plate and metal base plate. The bonding material also may provide electrical and thermal conductivity between the ceramic plate and the metal base plate. Some of the bonding material may be exposed to radicals during plasma processing. The radicals may degrade and/or erode the bonding material. Periodic replacement of the bonding material increases downtime and the cost of ownership.

The background description provided here is for the purpose of generally presenting the context of the disclosure. The information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, an electrostatic chuck system for use in a plasma processing chamber is provided. A conductive base plate is provided. A bond of a bonding material is bonded to a surface of the base plate on a first side of the bond. A ceramic plate is bonded to a second side of the bond. A protective strip surrounds the bond and extends between the conductive base plate and the ceramic plate, wherein the protective strip comprises at least one of an anodized strip, a ceramic tape strip, and a coated aluminum strip.

In another manifestation, a method for providing an electrostatic chuck system is provided. A conductive base plate is provided. The conductive base plate is bonded to a ceramic plate using a bonding material to form a bond. A protective strip is placed around the bond, wherein the protective strip extends between the conductive base plate and the ceramic plate, wherein the protective strip comprises at least one of an anodized strip, a ceramic tape strip, and a coated aluminum strip.

These and other features of the present disclosure will be described in more detail below in the detailed description and in conjunction with the following figures.

### BRIEF DESCRIPTION OF THE DRAWINGS

The disclosed embodiments are illustrated by way of example, and not by way of limitation, in the figures of the accompanying drawings and in which like reference numerals refer to similar elements and in which:

FIG. 1 is a high level flow chart of a process that may be used in some embodiments.

FIGS. 2A-E are schematic cross-sectional views of an electrostatic chuck system used in some embodiments.

FIG. 3 is a top view of the protective strip used in some embodiments.

FIG. 4 illustrates a schematic layout of an etch reactor that may be used in some embodiments.

FIG. 5 is a schematic cross-sectional view of an electrostatic chuck system used in some embodiments.

FIG. 6 is a schematic cross-sectional view of an edge seal used in some embodiments.

FIG. 7 is a schematic cross-sectional view of an edge seal used in some embodiments.

FIG. 8A illustrates a partial cross-sectional view of the base plate bonded to a ceramic plate by a bond surrounded by a ring comprising a segmented anodized ring wrapped in a polymer coating.

FIG. 8B is a cross-sectional view of segments of a segmented anodized ring wrapped in a polymer coating.

### DETAILED DESCRIPTION

Embodiments will now be described in detail with reference to a few of the embodiments thereof as illustrated in the accompanying drawings. In the following description, specific details are set forth in order to provide a thorough understanding of the present disclosure. However, the present disclosure may be practiced without some or all of these specific details, and the disclosure encompasses modifications that may be made in accordance with the knowledge generally available within this field of technology. Well-known process steps and/or structures have not been described in detail in order to not unnecessarily obscure the present disclosure.

Certain electrostatic chuck (ESC) systems may require bonding a ceramic material to a heat sinking (cooling) base plate made from metal. In some ESC systems, a ceramic plate is bonded to a metal base plate by a bonding material. The bonding material is sufficiently flexible to accommodate different coefficients of thermal expansion for the ceramic plate and metal base plate over a broad temperature range. The bonding material may also provide electrical and thermal conductivity between the ceramic plate and the metal base plate. The bonding material may be eroded when exposed to a plasma. The erosion of the bonding material causes thermal non-uniformities of the ceramic plate and substrate, causing process non-uniformities. Replacement and/or preparation of the bonding material increase chamber downtime and increase the cost of ownership. Previously, an O-ring would be provided to protect the bonding material. Although the O-ring would reduce exposure of the bonding material to radicals during plasma processing, the bonding material would still be exposed to radicals. In addition, the O-ring would degrade increasing the exposure of the bonding material to radicals. Replacement of the degraded O-ring and the bonding material increases downtime and the cost of ownership.

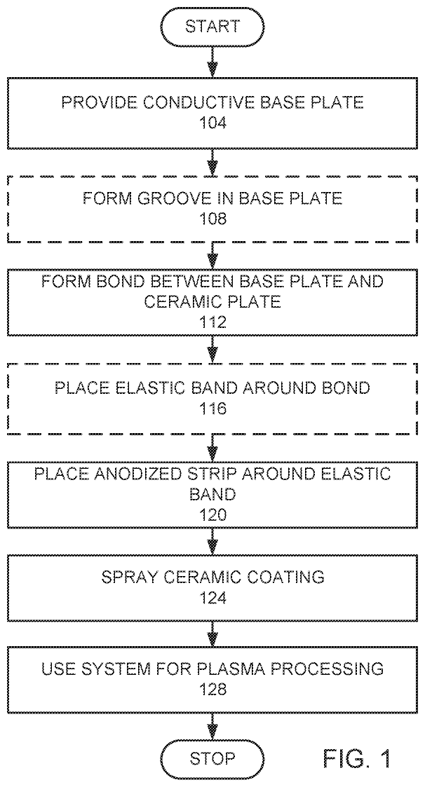

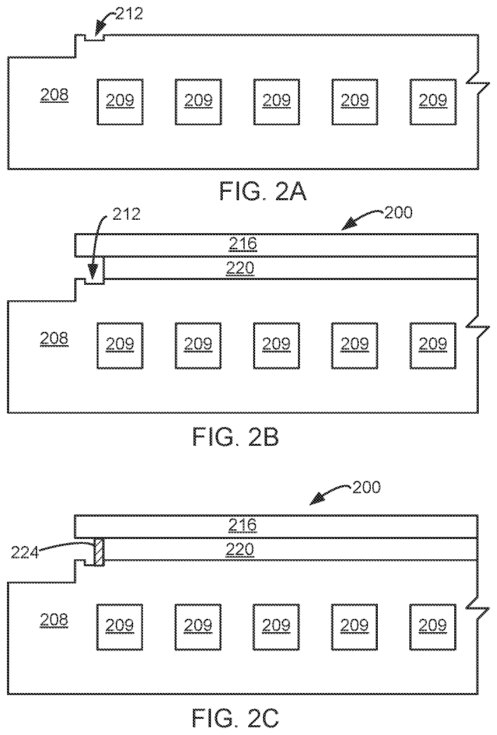

To facilitate understanding, FIG. 1 is a high level flow chart of a process used in some embodiments. A conductive base plate of an electrostatic chuck (ESC) system is provided. FIG. 2A illustrates a partial cross-sectional view of a base plate 208. In some embodiments, the base plate 208 is made of metal. In some embodiments, the base plate 208 may contain channels 209 for gas or liquid flow. These channels may, for example, be formed in complex distribution channels in order to cool or heat the base plate 208. In some embodiments, the base plate 208 is formed from at least one of aluminum alloy (Al) or aluminum-silicon carbide (Al—SiC).

A groove 212 is formed in the base plate 208. In some embodiments, the groove 212 is formed after the base plate 208 is provided. In some embodiments, the groove 212 is formed when the base plate 208 is formed. In some embodiments, the groove 212 is not formed since some embodiments do not use a groove.

The conductive base plate is bonded to a ceramic plate using a bonding material to form a bond (step 112) to form an ESC system. FIG. 2B illustrates a partial cross-sectional view of the base plate 208 bonded to a ceramic plate 216 by a bond 220 of a bond material to form the ESC system 200. In some embodiments, the ceramic plate 216 contains aluminum oxide or aluminum nitride. In some embodiments, the bond 220 comprises silicone.

An elastic band is placed around the bond 220 (step 116). FIG. 2C illustrates a partial cross-sectional view of the elastic band 224 placed around the bond 220. In some embodiments, the bond 220 comprises silicone. In some embodiments, the elastic band 224 is an O-ring. In some embodiments, the elastic band 224 is stretched to place around the bond 220. The elastic band 224 then contracts to provide a tight fit around the bond 220. Some embodiments may not use an elastic band 224.

In some embodiments, the elastic band 224 comprises silicone rubber with a conductive filler that is at least one of thermally conductive and electrically conductive. In some embodiments, the bond 220 may also contain conductive filler. If the elastic band 224 and bond 220 are equally thermally conductive and electrically conductive, heat and electrical fields may pass uniformly through both the elastic band 224 and bond 220, so that heat and/or electrical charge may be uniform across a substrate. As a result, the substrate may be more uniformly processed.

In some embodiments, the elastic band 224 may contain at least one of silicone rubber, fluoroelastomers (FKM), perfluoroelastomers (FFKM, PFA), and fluorosilicone (FVMQ, FMQ, FPM, FSI). In some embodiments, the elastic band is able to stretch to at least 25% of the original length. Therefore, the ring-shaped elastic band is able to have an elongation at break of at least 100%. Elongation at break is a term of art defined as a ratio between increased length at the time of breakage divided by initial length and is expressed as a percentage.

In some embodiments, conductive filler may be mixed with the silicone rubber gel. In some embodiments, the conductive filler may be one or more of metal particles, such as copper, aluminum, or silver, and carbon structures, such as graphene, nanoparticles and nanotubes, and semiconductor materials, such as silicon or doped silicon.

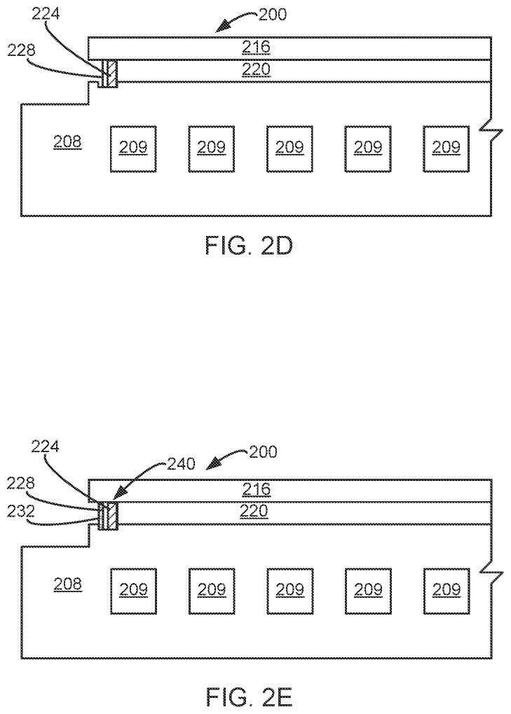

A protective strip is placed around the elastic band 224 and the bond 220 (step 120). FIG. 2D illustrates a partial cross-sectional view of a protective strip 228 placed around the elastic band 224 placed around the bond 220. FIG. 3 is a top view of the protective strip 228. In some embodiments, the protective strip 228, comprises at least one of an anodized strip, a ceramic tape strip, and a coated aluminum strip. In some embodiments, the anodized strip comprises an aluminum strip with an anodized surface (anodized aluminum strip), such as an aluminum ring 304 with an anodized outer surface 308. In some embodiments, a ceramic tape comprises a ceramic strip. Ceramic tape is a general terminology for a flexible ceramic strip. In some embodiments, ceramic tape has an adhesive. In some embodiments, the ceramic tape does not have an adhesive. In some embodiments, the coated aluminum strip comprises aluminum or aluminum alloy with a plasma resistant coating of at least one of alumna, yttria, or another ceramic. The coating may be applied either before or after the aluminum strip is put in place. In some embodiments, the protective strip 228 has a slit 312 in order the allow the protective strip 228 to expand in order to be placed around the elastic band 224 and the bond 220 and in order to provide tight contact between the protective strip 228 and the elastic band 224 and bond 220 over a wide temperature range. In some embodiments, the slit 312 makes the protective strip 228 a cut ring. In some embodiments, the aluminum ring 304 comprises an aluminum mesh or an aluminum alloy mesh, to form an anodized aluminum mesh or a coated aluminum mesh. In some embodiments, the protective strip 228 comprises a ceramic mesh.

A ceramic spray coating is sprayed over the protective strip 228. FIG. 2E illustrates a partial cross-sectional view of protective strip 228 after a ceramic coating 232 has been sprayed on the outside surface of the protective strip 228. In some embodiments, an edge seal 240 is formed by the elastic band 224, the protective strip 228, and the ceramic coating 232. In some embodiments, the ceramic spray coating is applied using a plasma spray, such as an atmospheric plasma spray. Atmospheric plasma spraying is a type of thermal spraying in which a torch is formed by applying an electrical potential between two electrodes, leading to the ionization of an accelerated gas (a plasma). Torches of this type can readily reach temperatures of thousands of degrees Celsius, liquefying high melting point materials such as ceramics. Ceramic particles are injected into the jet, melted, and then accelerated towards the protective strip 228 so that the molten or plasticized material coats the surface of the component and cools, forming a solid, conformal coating. In some embodiments, the thermal spraying provides a layer with a thickness in the range of 10 μm to more than 1000 μm. Various embodiments may use various spraying processes, such as at least one of thermal spray processes such as wire arc spraying, air plasma spraying, atmospheric plasma spraying, suspension plasma spraying, low-pressure plasma spraying, and very low-pressure plasma spraying. Other spraying processes may be cold spraying, kinetic energy spraying, and aerosol deposition. In some embodiments, the ceramic coating 232 is sprayed in-situ on the protective strip 228, while the protective strip 228 is in place surrounding the bond 220.

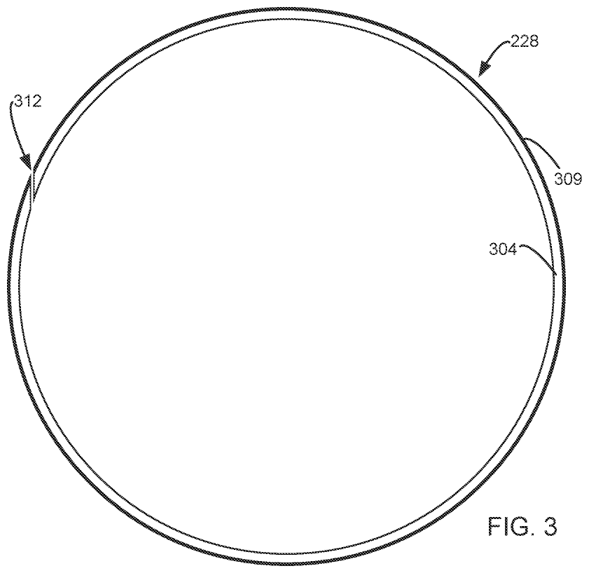

The ESC system 200 is used for plasma processing a substrate (step 128). FIG. 4 is a schematic view of an etch reactor with the ESC system 200, shown in FIG. 2E, embedded within. According to some embodiments, the etch reactor includes a plasma processing chamber system 400 comprising a gas distribution plate 406 providing a gas inlet and the ESC system 200, within a processing chamber 408, enclosed by a chamber wall 410. Within the processing chamber 408, a substrate 414 is positioned over the ESC system 200. The ESC system 200 comprises the ceramic plate 216 bonded to the base plate 208 by the bond 220. An edge ring 411 surrounds the ESC system 200. An ESC temperature controller 450 is connected to a chiller 418. In some embodiments, the chiller 418 provides a coolant to channels 209 in the base plate 208 of the ESC system 200. Various embodiments may be used in plasma processing chamber systems 400 that may operate at a temperature range where the ESC system 200 is cooled to temperatures of less than −40° C. and heated to temperatures above 200° C.

In some embodiments, a radio frequency (RF) source 430 provides RF power to a lower electrode. In some embodiments, the lower electrode is a facility plate 420 below the base plate 208 and separated from the base plate 208 by a mount O-ring 424. In some embodiments, 400 kilohertz (kHz) and 60 megahertz (MHz) power sources make up the RF source 430. In some embodiments, an upper electrode, the gas distribution plate 406, is grounded. In some embodiments, one generator is provided for each frequency. Other arrangements of RF sources and electrodes may be used in other embodiments. In some embodiments, a controller 435 is controllably connected to the RF source 430, an exhaust pump 428, and a gas source 432. An example of such plasma processing chamber system 400 is the Flex® etch system manufactured by Lam Research Corporation of Fremont, CA. The processing chamber 408 can be a CCP (capacitively coupled plasma) reactor or an ICP (inductively coupled plasma) reactor. The processing chamber 408 may be a dielectric etch chamber or conductive etch chamber. In some embodiments, the plasma processing chamber system 400 may be used for various plasma processes, such as etching, deposition, and cleaning.

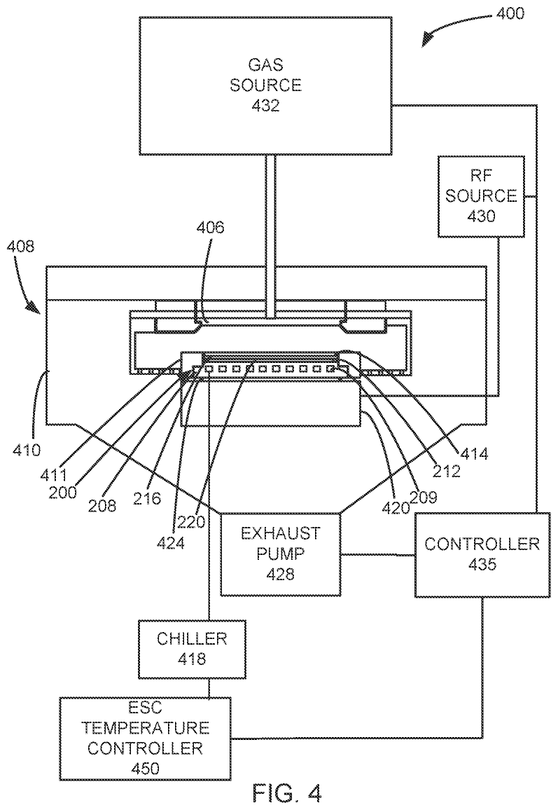

FIG. 5 illustrates a partial cross-sectional view of an ESC system 500 that is provided in another embodiment. In some embodiments, the ESC system 500 comprises a base plate 208 with channels 209 for gas or liquid flow bonded to a ceramic plate 216 by a bond 220. A protective strip 528 surrounds the bond 220. A ceramic coating 532 is sprayed on the protective strip 528. In some embodiments, an elastic band is not used. In some embodiments, an edge seal 540 is formed by the protective strip 528 and the ceramic coating 532.

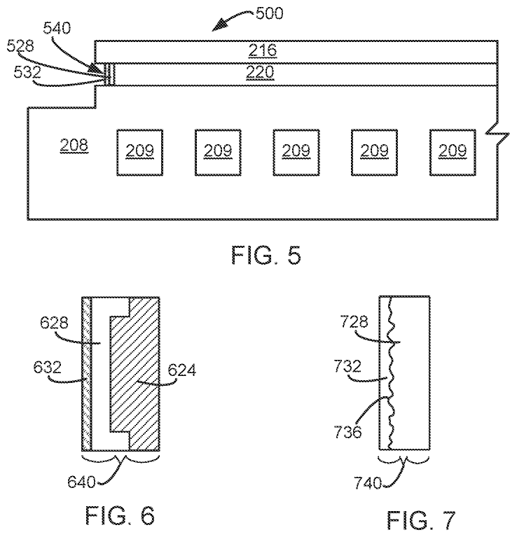

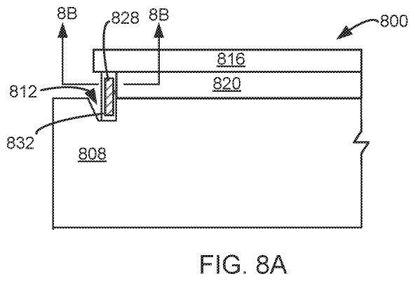

FIG. 6 is an enlarged cross-sectional view of an elastic band 624, protective strip 628, and ceramic coating 632 used in some embodiments. The protective strip 628 gas a C-shaped cross section in order to allow the protective strip 628 to have a stronger bond to the elastic band 624. In some embodiments, an edge seal 640 is formed by the elastic band 624, the protective strip 628, and the ceramic coating 632. FIG. 7 is an enlarged cross-sectional view of a protective strip 728 and ceramic coating 732 used in some embodiments. A surface 736 of the protective strip 728 is grit blasted in order to roughen the surface 736 before the ceramic coating 732 is sprayed on the surface 736 of the protective strip 728. The roughened surface 736 provides a stronger bond between the ceramic coating 732 and the protective strip 728. In some embodiments, an edge seal 740 is formed by the protective strip 728 and the ceramic coating 732.

In some embodiments, the ceramic coating may be at least one of alumina, yttria, and yttrium aluminum oxide (e.g., yttrium aluminum garnet, YAG). In some embodiments, the protective strip comprises an anodized aluminum mesh. In some embodiments, the anodized aluminum mesh is a Type III hard anodization. A Type III anodization process (also referred to as hard anodization or hard-coat anodization) is an anodization process that subjects aluminum to a sulfuric bath at a temperature of 0° C. to 3° C. and high voltage (up to 100 V) to create the oxide or “anodized” layer. In some embodiments, the base plate 208 is part of a pedestal.

It has been found that some embodiments with an elastic band 224, protective strip 228, and ceramic coating 232 are more resistant to plasma corrosion, thermal cycling degradation, and cracking than embodiments with an elastic band alone. Resistance to plasma corrosion and cracking is dependent on the Tg (Glass transition temperature) of the elastic band and stress corrosion cracking. (Tg (Glass transition temperature) is the temperature below which a polymer material becomes brittle. In addition, it has been found that some embodiments with an elastic band 224, protective strip 228, and ceramic coating 232 provide increased material consistency at the micro/nano level to provide uniform plasma resistance, manufacturing tolerance and variation, and sealability than embodiments with an elastic band alone. It has been found that some embodiments with a protective strip 528 and ceramic coating 532 are more resistant to plasma corrosion and cracking than embodiments with an elastic band 224, protective strip 228, and ceramic coating 232. In addition, it has been found that some embodiments with a protective strip 528 and ceramic coating 532 provide increased material consistency at the micro/nano level to provide uniform plasma resistance, manufacturing tolerance and variation, installation variability, and sealability than embodiments with an elastic band 224, protective strip 228, and ceramic coating 232.

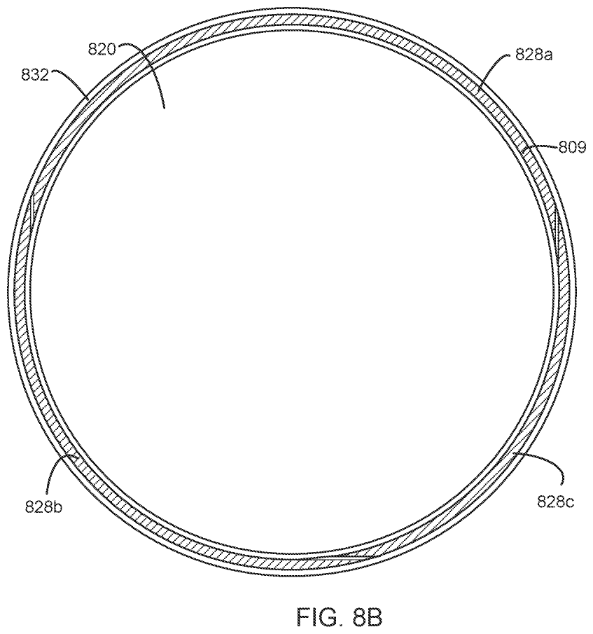

FIG. 8A illustrates a partial cross-sectional view of the base plate 808 bonded to a ceramic plate 816 by a bond 820 surrounded by a ring comprising segmented ring 828 wrapped in a polymer coating 832, wherein the protective strip comprises the segmented ring 828. FIG. 8B is a cross-sectional view of segments 828a, 828b, 828c of the segmented ring 828 wrapped in a polymer coating 832. In some embodiments, the polymer coating 832 provides an elastic coating. In some embodiments, the polymer coating 832 is in a C-shape that surrounds the segmented ring 828, so that the length of the polymer coating 832 forms a ring with the bond 820 inside the ring formed by the polymer coating 832. The groove 812 in the base plate 808 is sloped to facilitate easier placement of the anodized ring 828 and polymer coating 832 into the groove 812. Using the segmented anodized ring 828a, 828b, 828c and the polymer coating 832 provides an elastic ring that can be placed around the bond 820. The ends of the segments 828a, 828b, 828c of the segmented anodized ring 828 are beveled to reduce or eliminate any radial line of sight. In some embodiment, the portion where the ceramic plate 816 contacts the polymer coating 832 the ceramic plate 816 is polished. The polished surface provides an improved plasma seal between the ceramic plate 816 and the polymer coating 832. In some embodiments, the protective strip may be a single piece with a slit or more than one segmented piece. In some embodiments, a ceramic coating is applied to an outer side of the ring formed by the polymer coating 832, where the bond 820 is on the inner side of the ring formed by the polymer coating 832.

In some embodiments, the edge seal has a lifetime that is as long as the lifetime of the ESC system. In some embodiments, the lifetime of the ESC system is at least 5000 RF hours. In contrast, an elastic band alone provides protection sufficient protection of the bond for 500 to 1500 RF hours. Not only does the elastic band have a shorter lifetime, but the elastic band provides less protection so that the bond is more exposed to plasma by using only an elastic band than exposure to plasma caused by some embodiments. The extended protection provided by some embodiments reduces downtime and the cost of ownership. In addition, since the lifetime of the bond is extended to be about the lifetime of the ESC system, the bond is considered non-consumable. In addition, the reduction of bond degradation improves processing uniformity. Some embodiments, provide bond protection over a temperature range of −80° C. to 80° C. The cut ring formed by the protective strip 528 provides sufficient elasticity in order to provide protection over a temperature range. The use of a cut ring or segmented ring allows for the use of a protective strip 528 of a protective strip material that can break easily (e.g., has an elongation at break of less than 1%) and allows for the protective strip to be wrapped around the bond. As a result, the protective strip 528 does not form a complete ring that is stretched when put in place. In contrast, the elastic band 224 is of a material that has an elongation at break of greater than 50%. The groove used in some embodiments disrupts the plasma path to the bond further reducing plasma erosion of the bond and increasing the lifetime of the bond. In some embodiments, the bond forms a complex pattern, in order to facilitate various features, such as cooling of the ceramic plate. In some embodiments, the forming of the bond uses a deposition process that does not allow placement of the edge seal until after the bond is formed. In some embodiments, the material used to form the bond 820 may be placed around the protective strip 528 to hold the protective strip 528 in place.

While the disclosure has been described in terms of several preferred embodiments, there are alterations, permutations, and various substitute equivalents, which fall within the scope of this disclosure. There are many alternative ways of implementing the methods and apparatuses disclosed herein. It is therefore intended that the following appended claims be interpreted as including all such alterations, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. An electrostatic chuck system for use in a plasma processing chamber, comprising:
a conductive base plate;
a bond of a bonding material bonded to a surface of the base plate on a first side of the bond;
a ceramic plate bonding to a second side of the bond; and
a protective strip surrounding the bond and extending between the conductive base plate and the ceramic plate, wherein the protective strip comprises at least one of an anodized strip, a ceramic tape strip, and a coated aluminum strip.

2. The electrostatic chuck system, as recited in claim 1, further comprising a ceramic coating on an outside of the protective strip, wherein the protective strip and the ceramic coating form an edge seal for the bond.

3. The electrostatic chuck system, as recited in claim 2, further comprising an elastic band between the bond and the protective strip, wherein the elastic band is part of the edge seal.

4. The electrostatic chuck system, as recited in claim 2, wherein the ceramic coating comprises at least one of alumina, yttria, and yttrium aluminum oxide.

5. The electrostatic chuck system, as recited in claim 4, wherein the ceramic coating is a ceramic spray coating.

6. The electrostatic chuck system, as recited in claim 1, wherein the protective strip is an anodized aluminum strip.

7. The electrostatic chuck system, as recited in claim 1, further comprising a groove in the conductive base plate, wherein part of the protective strip fits into the groove.

8. The electrostatic chuck system, as recited in claim 1, wherein the protective strip is at least one of an anodized aluminum mesh, a coated aluminum mesh, and a ceramic mesh.

9. The electrostatic chuck system, as recited in claim 1, wherein the protective strip is a cut ring or a segmented ring.

10. The electrostatic chuck system, as recited in claim 1, further comprising an elastic coating on the protective strip.

11. A method for providing an electrostatic chuck system, comprising:
providing a conductive base plate;
bonding the conductive base plate to a ceramic plate using a bonding material to form a bond; and
placing a protective strip around the bond, wherein the protective strip extends between the conductive base plate and the ceramic plate, wherein the protective strip comprises at least one of an anodized strip, a ceramic tape strip, and a coated aluminum strip.

12. The method, as recited in claim 11, further comprising spraying a ceramic coating over the protective strip.

13. The method, as recited in claim 12, further comprising placing an elastic band around the bond before placing the protective strip around the bond.

14. The method, as recited in claim 12, wherein the spraying the ceramic coating is a plasma spraying of the ceramic coating.

15. The method, as recited in claim 12, wherein the ceramic coating comprises at least one of alumina, yttria, and yttrium aluminum oxide.

16. The method, as recited in claim 11, wherein the protective strip is an anodized aluminum strip.

17. The method, as recited in claim 11, further comprising forming a groove in the conductive base plate, wherein part of the protective strip fits into the groove.

18. The method, as recited in claim 11, wherein the protective strip is at least one of an anodized aluminum mesh, ceramic mesh, and a coated aluminum mesh.

19. The method, as recited in claim 11, wherein the protective strip is a cut ring or a segmented ring.

20. The method, as recited in claim 11, further comprising an elastic coating on the protective strip.
